(19) United States
(12) Patent Application Publication
(10) Pub. No.: US 2021/0202811 A1
(43) Pub. Date: Jul. 1, 2021

(54) Compliant and electro-migration resistant interconnects for CSP

(71) Applicant: Scott Moore Zimmerman, Basking Ridge, NJ (US)

(72) Inventor: Scott Moore Zimmerman, Basking Ridge, NJ (US)

(21) Appl. No.: 16/012,033

(22) Filed: Jun. 19, 2018

(51) Int. Cl. H01L 33/62; H01L 33/48

(52) U.S. Cl. CPC H01L 33/62; H01L 33/507; H01L 33/483

(57) ABSTRACT

Compliant interconnect based on deformable wires compressed against contacts on chip scale packages (CSP). Including deformable rubbery overcoat on at least one of the CSP. The use of substantially optically transmitting overcoat means to secure the assembly is also disclosed. The use of various wires including but not limited to gold, silver, aluminum, carbon nanotube yarns, and composite wires also disclosed.

### REFERENCE TO PRIOR APPLICATION

This application claims the benefit of U.S. Provisional Patent Application Ser. No. 62/521,966, which was filed on Jun. 10, 2017, which is herein incorporated by reference.

### BACKGROUND

Sustainable designs require that products use the minimal amount of raw materials, raw materials and chemicals used be non-hazardous, the design allows for economical reuse or refurbishment of those materials, and that the manufacturing process be minimalistic, energy efficient, and safe as well. Unfortunately, eliminating hazardous materials such as those on the Red List, can impact reliability. One example is lead, the conversion to lead free solders has created electro-migration issues in many applications causing shorting and other defects in interconnects. With goal of reducing cost of manufacturing chip scale packages (CSP) have been designed for direct die attach to substrates not only has this led to whiskering but it has also created stress migration problems associated with the piezoelectric nature of the design which also impact reliability. The need exists for compliant and electro-migration resistant interconnects for these types of smaller devices which take into account not only the heat and light emitted by LED CSPs but also the vibrations induced. In addition cradle to cradle initiatives require novel approaches to reuse or refurbishing the majority of the product rather than making new product from scratch every time the product fails or is upgraded. The combination of higher reliability and cradle to cradle design leads to truly sustainable products.

Electro-migration occurs with any conductor but is especially prevalent in tin and silver based solders and interconnects. The smaller the grain boundaries the more likely it becomes to have a whisker problem. While temperature and electrolytic agents like water, sulfur, and cleaning materials can accelerate the problem, it is also proposed that the piezoelectric forces exerted by nitride based devices may also be exacerbating the problem. Activation energies are less than 1 volt which allows for even line noise to enhance whisker growth. The use of pulse width modulation (PWM) dimming schemes also can contribute to enhanced whisker growth due to mechanical stress effects. Anode to Cathode spacing can be less than 200 microns with anywhere from 3V to 50V potential difference being used. Current densities can exceed 100 A/cm2 and underfills can adversely impact the optical properties of the device. Underfills also are susceptible to degradation due to piezoelectric forces discussed earlier.

In general a compliant joint is needed for CSP lighting applications which mitigates the electro-migration issues and dampens or eliminates the piezoelectric forces created by the anisotropic nature of the CSP itself.

### SUMMARY OF THE INVENTION

This invention relates to the formation of a compliant interconnects for CSP LEDs. In one embodiment a pocket is formed in a ceramic, glass, or single crystal via a forming means including but not limited to laser ablation, molding, chemical etching, ultrasonic machining, pressing, or other forming means. Fiber based laser machining is preferred due to it energy efficiency, lack of chemicals, long life, lack of tool wear, and repeatability. Heat is dissipated or spread via the ceramic, glass, or single crystal material from the LED die embedded therein to the surrounding ambient. In general, a compliant overcoat which may or may not be luminescent is compressed within the light source and aligned via micro features. In its simplest form pockets are used to align the CSP and trenches used to align electrically conductive wires. Most preferred is alignment in which the CSP itself aligns itself to the wires. Alternatively, within the pocket micro contacts substantially pyramidal in shape are formed via molding, laser ablation or other means. A gold contact layer is formed on these micro contacts via but not limited to aerosol jet printing, inkjet printing, laser electroplating, and mechanical means such that at least one contact point is formed. For a 2 contact CSP two gold micro contacts are formed in this manner separated electrically. The CSP is placed in the pocket such that the cathode and anodes are electrically contacted by the appropriate micro contact points. The height of CSP is substantially taller than the pocket such that once placed in the pocket appropriately a cover glass can be used to compress the CSP against the substantially gold contacts or wires. Alternately a micro lead frame can be captured between the pocket walls and the CSP contact. The micro leadframe may be formed via mechanical, chemical etching or laser ablation means. The most preferred method for electrical connection is a nickel gold coated round wire. The round shape of the wire allows for reliable gold on gold contact when placed in compression. In most cases CSP LEDs have phosphor/silicone overlays. In this invention the rubber like, compliant nature of the phosphor/silicone overlay is used to not only form a compliant electrical connection once the cover glass is in place but also act to dampen out any vibrational forces created by the piezoelectric nature of the nitride LED die. For applications which do not required a phosphor/silicone overlay a silicone encapsulant may be also be used. As such RGB die as well as phosphor coated LED die may be used.

In general, the intent of this invention is to demonstrate compliant electrical contacts. The use of deformable wires such as gold, carbon nanotube yarns, composite of inorganic and organic materials are disclosed.

### BRIEF DESCRIPTION OF DRAWINGS

FIG. 1 depicts LED filament

FIG. 2 depicts CSP soldered to substrate

FIG. 3 depicts whisker formation between cathode and anode of CSP

FIG. 4 depicts various mountings of a CSP in laser cut pocket

FIG. 5 depicts light source with compliant wire contacts

FIG. 6 depicts CSP in pocket with cover glass and clamping/interconnect mechanism

FIG. 7 depicts two CSP within pocket in polycrystalline ceramic

FIG. 8 depicts bidirectional light source with encapsulated CSP

### DETAILED DESCRIPTION OF DRAWINGS

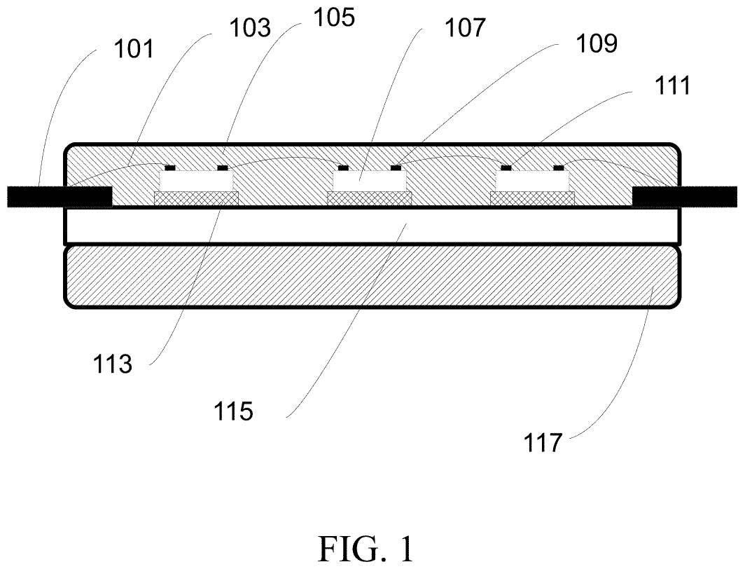

FIG. 1 depicts prior art of a LED filament light. Glass or sapphire substrate 115 has multiple LED die 107 mounted via adhesive layer 113. Wirebonds 103 are used to connect the multiple LED die 107 to contacts 109 and 111 depending on the desired series and/or parallel interconnect desired for multiple LED DIE 107. Pin 101 is wirebonded to and provides external contact for the LED filament. Pin 101 may also mechanically be secured to glass or sapphire substrate 115 as required. Phosphor coating 105 is typically used to encapsulate the assembly to protect the wirebonds, provide for wavelength conversion, and diffuse the light emitted. This approach however suffers from high operating temperature due to lack of reasonable thermal conduction path as the low thermal conductivity phosphor coating 105 acts like an insulator to the underlying die 107. In most cases LED filament sources are enclosed in an argon glass envelope depending on convective cooling of the assembly. In general this approach typically does 100 to 200 lumen output levels and is not mechanically robust enough to be used outside the protective envelope.

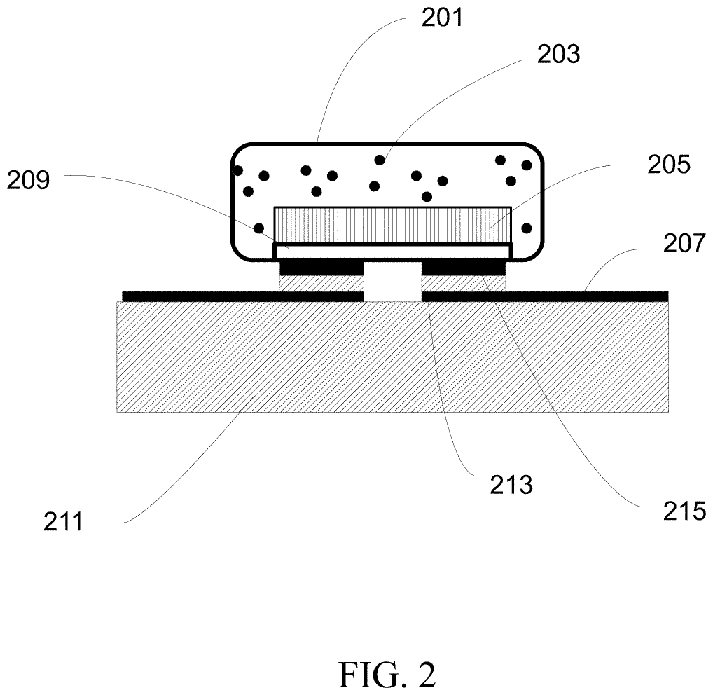

FIG. 2 depicts prior art of a soldered chip scale package (CSP) to an underlying substrate. The CSP typically consists of a patterned sapphire growth substrate 205 with nitride active region 209 on which there are cathode and anode contacts 215 and silicone/phosphor overcoat 201 containing phosphor particles 203. It should be noted that silicone/phosphor over 201 similarly thermally insulates the encapsulated LED die as in the previous LED filament prior art. The CSP is typically thermally and mechanically attached to an underlying substrate 211 via thick film solder paste 213 on traces 207. This die attachment method is both mechanically rigid and requires that the assembly be exposed to over 220C soldering temperatures. Stresses are induced during the soldering process based on thermal expansion mismatches between the LED die (comprising 209,205, and 215 elements), solder paste 213, substrate 211, and traces 207. In general, there can be over an order of magnitude difference in the thermal expansion coefficients using this assembly method. Besides the initial thermal stresses introduced during die attachment, there are operational stresses induced during usage. Finally it should be noted that active layer 209 is piezoelectric and expands and contracts based on the electrical input waveform. To the authors knowledge the impact of this piezoelectric stresses and how they impact electromigration have not been investigated thoroughly but field experience appears to indicate a link. Further patterned sapphire substrate 205 forms a bimorph with active layer 209 to further enhance the piezoelectric stresses in the devices as transient drive conditions are inputted to the CSP. These transient inputs can be intentional as with pulse width modulation (PWM) dimming or unintended as with ripple on the driver output. It should be noted that over 1 volt of ripple can be easily seen on most LED driver outputs. PWM typically operates between 100 Hz and 10 KHz. As such most LED lighting sources are exposed to significant vibrational stresses during normal operation. The intent of this invention is to use means and methods to dampen these vibrational stresses and minimize their impact on electromigration as well. While it is still somewhat unclear why vibrational stresses increase electromigration there is significant experimental data which supports this claim. In general whisker and other electromigration failure mechanism are not well understood, but what is understood is that CSP represents a significant challenge from the standpoint of high current density, voltage differences well above the activation energy of most metals, mechanically rigid structure, and the need for lead free solders. Even the use of underfills is problematic in that the underfill impacts the optical properties of the CSP via absorption losses and index matching to the silicone/phosphor overlay 201. More importantly the piezoelectric motion created during operation will tend to adversely impact the adherence of any underfill to the CSP. The need exists for compliant and low stress interconnects to CSP if long life lighting sources are to be realized.

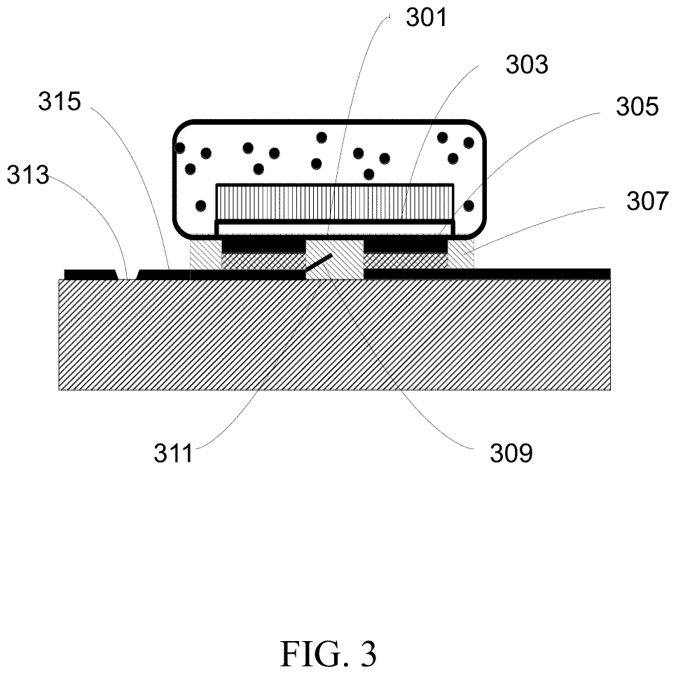

FIG. 3 depicts some of the possible failure mechanisms in CSPs. As stated earlier lead free solders are typically more susceptible to elecromigration especially if tin, and silver are used which is the case with most solder formulations. Typically a whisker 309 forms from one contact based on the polarity of the voltage bias.

This whisker can be several millimeters long has a propensity to follow imperfection in underfill 307, interfaces between surfaces, and other tortuous paths. Tin is especially likely to form these whiskers, however silver especially in the presence of water or sulfur containing gases (pollution) will also very readily electromigrate. The interface 301 between the bimorphic chip 303 and the underfill is constantly being mechanically stressed due to the bending induced as drive levels change. Over time this mechanical stress appears to degrade the adhesion between underfill 307 and the bimorphic chip 303. Similarly, solder joint 305 is being continually stressed by the bimorphic chip 303. Interface 311 may also be adversely impacted by these mechanical stresses. In general, bimorphic chip 303 can have a resonance in excess of 50 Khz and dominates both the mass and stiffness of solder joint 305 and interfaces 301 and 311. As such it is apparent that failures will occur within solder joint 305 and interfaces 301 and 311 as they are the weakest links in the attachment means. The need exists for methods and means to dampen out or elevate these mechanical stresses. It should also be noted that other galvanic defects 313 are also possible for exposed traces. It is therefore preferred that traces be encapsulated, inherently corrosion resistant, or otherwise protected from the environment in any design.

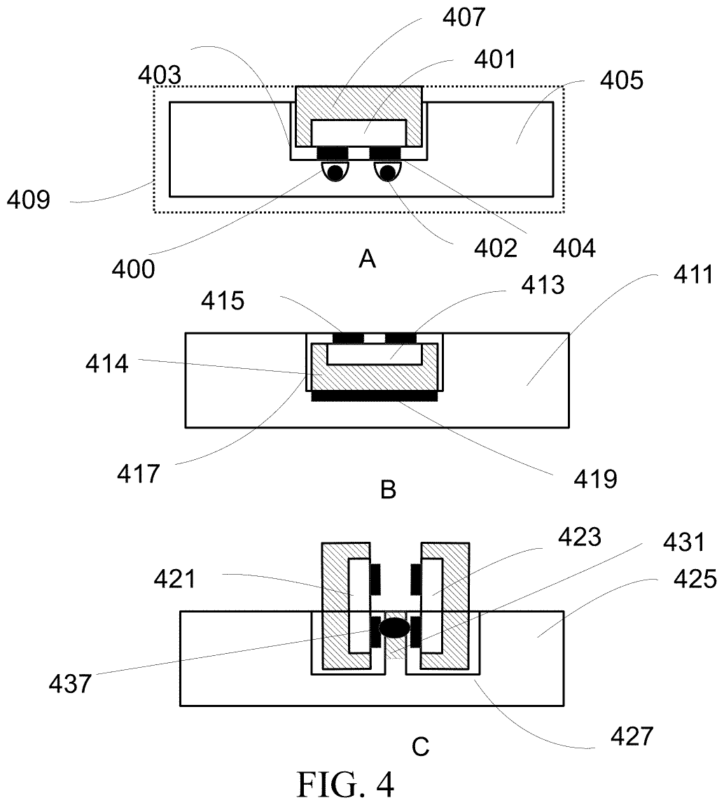

FIG. 4A depicts formation of at least one pocket 403 via one or more the following means, laser ablation, molding, ultrasonic machining, mechanical means, chemical means, or other micro machining methods. The pocket is most preferably formed in a thermally conductive optically transmitting material 405 like sapphire, glass, ceramics, polycrystalline materials such that both heat and light can be transmitted or coupled or spread via the thermally conductive optically transmitting material 405. As previously stated electrical interconnect can be formed via printing, aerosol jet, and other additive means as known in the art. Most preferably trenches 400 are formed with the pockets in thermally conductive optically transmitting material 405 such that wires 402 can be aligned and form a compliant interconnect to contact 404. As a preferred example, single crystal or translucent polycrystalline sapphire is used for thermally conductive optically transmitting material 405 with the pocket 403 and trenches 400 being formed via laser ablation using a NIR femtosecond fiber laser with at least 10 mJ of pulse energy with a repetition rate of 50 Khz or higher. The pocket 403 and trenches 400 are formed via a raster scan of a focused spot size of 20 microns or less. Typical machining time is under 10 seconds per pocket 403. The pocket 403 is dimensioned such that silicone/phosphor overlay 407 is substantially in physical and optical contact with the sidewalls of pocket 403 such that LED die 401 is mechanically held in place and silicone/phosphor overlay 407 can be used to dampen out vibrations from the piezoelectric stresses induced in the LED die 401 during operation and also align the contact 404 to wire 402 in the trench 400. It should be noted that using this approach unlike the prior art allows for thermal cooling of the silicone/phosphor layer 407 which represents approximately half the heat load, uses the silicone/phosphor overlay 407 as a vibrational isolation or dampener or shock absorber, acts as a self aligning element for the wires 402 and offers the opportunity to index match or otherwise optically couple the photons emitted by the LED die 401 (including photons created within silicone/phosphor over 407 which together from the CSP) into thermally conductive optically transmitting material 405. While not shown in this drawing wire 402 is connected electrically to an external contact or other means to provide power to the LED die 401 aligned via pocket 403 or be otherwise formed in or on thermally conductive optically transmitting material 405. It is also disclosed that a preferred embodiment of thermally conductive optically transmitting material 405 may include a highly scattering low absorption coating 409 with an alpha less than 0.001 cm-1 between 350 nm and 1 micron. Most preferably, coating 409 consists of plasma or flame sprayed high purity alumina with a coating thickness between 50 microns and 500 microns. The coating 409 maybe uniformly or non-uniformly coated on one or more surfaces of thermally conductive optically transmitting materials 405. It should be noted that silicone/phosphor overlay 407 may also be overcoated or otherwise mechanically held by coating 409. It is the intent of the invention to use mechanical means to compress or otherwise contain the CSP comprised by LED die 401 and silicone/phosphor overlay 407 such that the silicone/phosphor overlay 407 vibrationally dampens, isolates or otherwise mechanically supports the LED die 401 relative to the thermally conductive optically transmitting material 405 to some extent. FIG. 4B depicts CSP comprised of LED die 413 and compliant element 414 inverted as compared to FIG. 4A in pocket 417 within thermally conductive optically transmitting material 411. Optionally reflector 419 maybe formed within pocket 417 to form a waveguide condition within thermally conductive optically transmitting material 411. Again while not shown scattering coating described in FIG. 4A can be used to extract waveguided photons from the thermally conductive optically transmitting material 411 as desired. Alternately, scatter internal to thermally conductive optically transmitting material 411 may be used separately or with the spatially patterned scattering coating to extract photons as desired. In this embodiment contacts 415 are readily available for wire bonding, conductive adhesives, inkjet printing of conductive layers, aerosol jet printing, or mechanical means to connect the CSP electrically. While not shown a cover layer containing electrical contacts may also be used to mechanically, thermosonic, thermocompression or other contact means electrically connect one or more CSPs together as describe in FIG. 4a. FIG. 4C depicts the full or partial containment of one or more CSP 423 and 421 within pockets 427 within thermally conductive optically transmitting material 425. While the CSP 423 and 421 are shown in separate pockets in the figure an embodiment of the invention is CSP 423 and 421 in a single pocket with contact facing each other and contacts away from each other. In general the intent of this invention is to provide a thermal conduction path for the silicone/phosphor overlay while using the silicone/phosphor layer as dampening and mechanical holding means for the CSPs shown. In all embodiments the formation of trenches and alignment features 431 can be used to allow for electrical interconnect means 437. Further figures will deal with electrical interconnect means 437 associated with CSPs in pockets with dampening means.

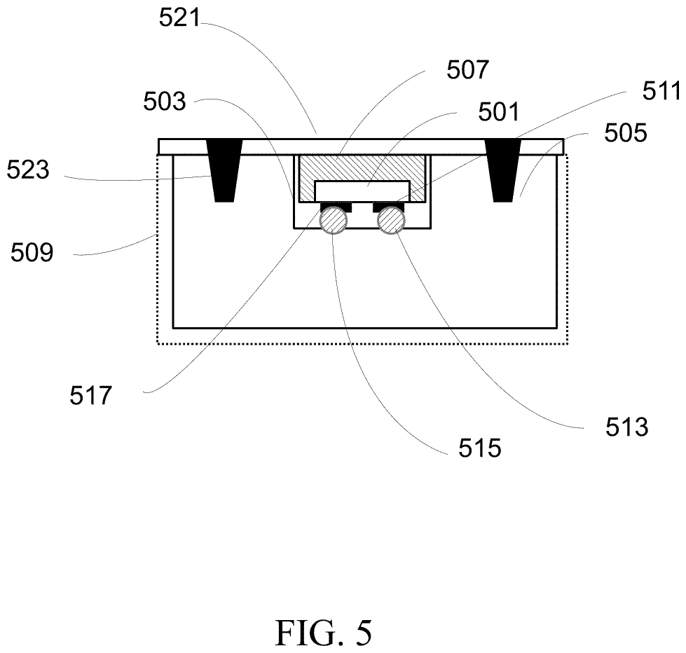

FIG. 5 depicts at least one LED die 501 with compliant overcoat 507 which maybe transparent, translucent, luminescent, or non-luminescent. LED die 501 has at least two contacts 517 and 511 which provide power to LED die 501. Substrate 505 is substantially non absorbing for the light emitted by LED Die 501 and compliant overcoat 507 and may include but not limited to glass, sapphire, polycrystalline sapphire, alumina, glass/ceramic composites, spinel, YAG, YSZ, and luminescent and non-luminescent transparent thermally conductive materials with formed features 503 in substrate 505 and/or overlay 521 which serve to align and otherwise locate LED die 501 and compliant overcoat 507 and its associated contacts 517 and 511 to wires 515 and 513 respectively. Features 503 are most preferably laser cut using sub picoseconds laser micromachining such that minimal slag and absorptive material is formed during machining. Galvo based micromachining is most preferred due to speed and accuracy of the system. Overlay 521 provides compressive force against compliant overcoat 507 and is bonded or otherwised attached to substrate 505 by staking elements 523 which may include but not limited to mechanical fasteners, welding, adhesives, or other attachment means. Overlay 521 maybe a metal, ceramic, glass, plastic, or wood. Most preferred for Overlay 521 are materials with thermal conductivity greater than 1 W/mK to enhance thermal cooling of the compliant overcoat 507 While the figure shows the staking element only extending into substrate 505, an embodiment of this invention allows for through holes in substrate 505 such that mechanical fastening can be facilitated. Optionally overcoat 509 may be used to create substantially different illumination patterns to be emitted from substrate 505 and overlay 521. This bidirectional nature allows for a wide range of optical fixtures to be created using a single light source. Overcoat 509 may include but not limited to diffusive layer, reflective layer, colored filter, porous reflectors, microlenses, and thermal cooling elements. The depth of pocket 503 determines the amount of light coupled into the substrate 505.

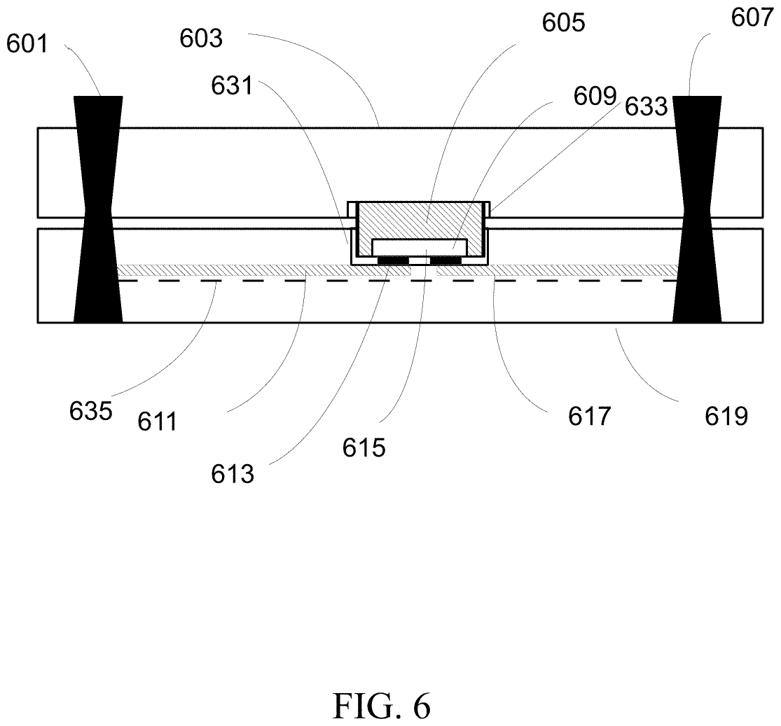

FIG. 6 depicts a bi-directional light source in which the clamping elements 601 and 607 also serve to provide external contacts for the light source. In this embodiment the gold wire 611 and 617 electrically attach to clamping elements 601 and 607 respectively using attachment means including but not limited to solder, microwelding, resistance welding, flash welding, mechanical staking, and other attachment means. Again features 631 and 633 are formed in substrate 619 and top plate 603 respectively. Trench 635 for wires 611 and 617 and clamping element 601 and 607 are also formed using laser micromachining or other formation means including but not limited to pressing, molding, or ultrasonic machining. Most preferably fine features for trenches and pockets are done using femtosecond NIR fiber laser for accuracy, speed, quality and shaping.

Dicing and through hole cutting as required to segment substrate 619 and 603 and features for clamping elements 601 and 607 are done using Quasi CW NIR fiber lasers for speed, cut shaping, and minimal slag. The tapered nature of Quasi CW NIR fiber lasers is used to enhance the clamping mechanism. The incorporation of fibers or other reinforcement elements into clamping elements 601 and 607 is also disclosed. Compliant element 605 again forces wire 611 and 617 against contact 613 and 609 respectively on chip scale package 615. The intent of this invention is to create lighting sources that use a minimal amount of natural resources and limited amount of chemicals in its manufacturing process. By removing the clamping elements 601 and 607 the light source comes apart into its base materials which can be easily refurbished, repurposed, or recycled once the useful its life has passed. To the authors knowledge this is the first cradle to cradle light source design disclosed.

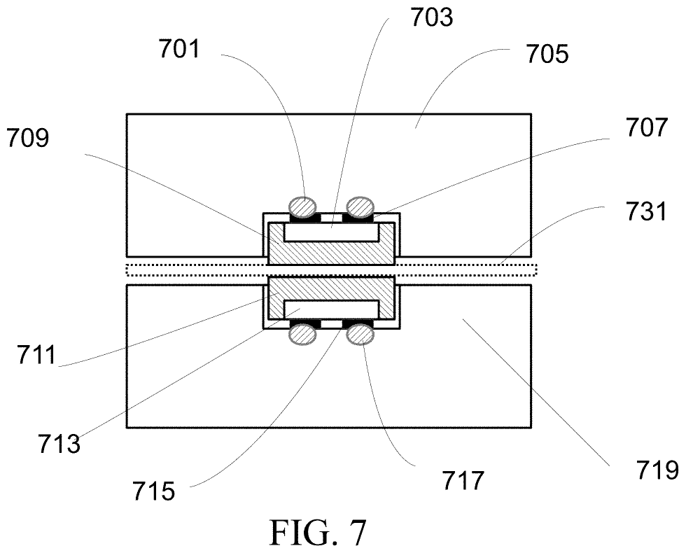

FIG. 7 depicts a light source in which at least two CSP consisting of die 713 and 703 with compliant element 709 and 713 respectively are substantially compressed together. The advantage of this approach is that two different color temperature or colors can be mixed effectively thereby creating a simple color changing element. Optional splitter 731 can consist of a blue reflective filter, a diffuser, a thin transparent thermally conductive heatspreader such a thin alumina ribbon from Corning, a glass waveguide, an array of scattering optical fiber such as Corning Fibrance fibers, glass frit, adhesive or a thin luminescent element such as CeYag ribbon again from Corning. Substrates 719 and 705 are used to clamp contacts such as wires 717 and contact 715 together. In general, wires such as 701 round such that localized contact is possible. Most preferable wires have nickel and gold overcoats for durability, current carrying capability, and reliability. Contacts such as contact 707 typically also have a gold overcoat for reliability and solderability. While soldering is an embodiment of this invention and is claimed to create a more reliable joint due to the ability of the wire such as 701 to move relative to substrate 705 it is most preferred that solder is not used in this design due to electro migration associated with lead free solders. Alternately, thermocompression, laser welding, or other gold to gold bonding means may be used if to further enhance the interconnect. While round wires for wires such as 701 are preferred wire forms, other shapes, multiple stranded wires, metal coated polymeric fibers, micro diamond plated wires, square wires, carbon nano tube yarns, and other shapes are disclosed. Most preferably low thermal expansion alloys or high stiffness alloys are used for the core materials. As known in the art, grain size control and drawing techniques may be used to enhance the reliability of this approach. In general, the intent of this invention is to use the minimum amount of raw materials and to allow for efficient reuse, refurbishment, and recycling of the light sources.

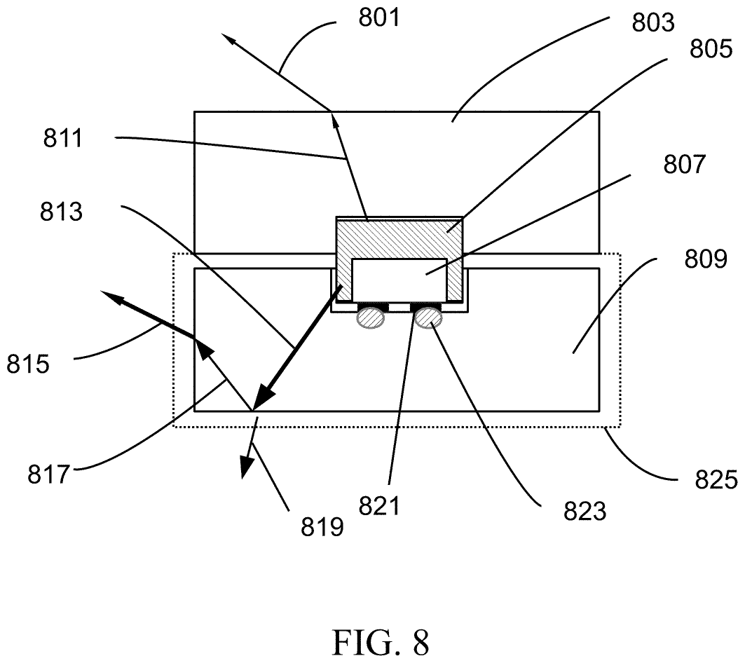

FIG. 8 depicts a bi-directional light source based on the disclosed invention. At least one CSP consisting of LED die 807 and compliant luminescent element 805 is compresed between substantially clear top element 803 and substantially clear bottom element 809 with overcoat 825. Again electrical contact is made to LED die 807 via contact 821 to wire 823 which eventually but not shown exits the light source as previously disclosed. In the case where overcoat 825 is a low loss diffuser such as high purity alumina powder spray coated or otherwise attached to substantially clear bottom element 809. Most preferably substantially clear bottom element 809 is allows for significant lateral propagation of CSP rays 813 such that diffuse overcoat 825 creates a recycling cavity as shown by transmitted rays 819 and 815 and reflected rays 817. As such high purity sapphire, glass, polycrystalline sapphire, spinel and other substantially clear materials are preferred for bottom substrate 809. As the emission from the CSP approximates an isotropic emitter the relative depth of the pocket features in bottom substrate 809 and top substrate 803 determines along with the overcoat 825 determines the direction of the rays emitted. For the top substrate with no overcoat emitted ray 811 obeys Snell's law as shown with output ray 801. By mixing and matching overcoats and pocket depths virtually any far field distribution can be created.

The invention claimed is:

1. A compliant interconnect comprising at least one semiconductor chip with a deformable overcoat containing at least two contacts, at least one thermally conductive optically transmitting substrate containing one or more pockets, a restraining means, and at least two deformable wires wherein said at least two deformable wires are deformed and form electrical and mechanical contact with said at least two contacts by said at least one thermally conductive optically transmitting substrate and said restraining means

2. The compliant interconnect of claim 1 where said deformable coating contains at least one luminescent element

3. The compliant interconnect of claim 1 wherein said deformable coating is silicone.

4. The compliant interconnect of claim 1 wherein said substrate consists of one or more of the following materials; sapphire, glass, luminescent glasses, composites, or other thermally conducting optically transmitting luminescent materials.

5. The compliant interconnect of claim 1 wherein the deformable wires consist of one or more of the following materials; gold, carbon nanotube yarns, electrically conductive inorganic/organic wires, silver, aluminum, gold plated metal wires.

6. A compliant interconnect comprising; at least one semiconductor chip with one or more contacts, at least one carbon nanotube yarn wire, and at least one overcoat wherein said overcoat mechanically and electrically maintains contact between said one or more contacts and said at least one carbon nanotube yarn wire.

7. The compliant interconnect of claim 6 wherein at least two LED chips with at least one or more contacts compress said at least one carbon nanotube yarn wires and are secured by said overcoat such that a substantially isotropic emitter is formed.

8. The compliant interconnect of claim 7 wherein additional thermally conductive optically transmitting substrates are also used.
